(19) United States
(12) Patent Application Publication
(10) Pub. No.: US 2024/0274750 A1
(43) Pub. Date: Aug. 15, 2024

(54) LIGHT-EMITTING DEVICE AND METHOD FOR MANUFACTURING THE SAME, DISPLAY PANEL AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Zhigao LU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/637,476

(22) Filed: Apr. 17, 2024

Related U.S. Application Data
(63) Continuation of application No. PCT/CN2022/115074, filed on Aug. 26, 2022.

(51) Int. Cl. H01L 33/06; H01L 25/075; H01L 33/00

(52) U.S. Cl. CPC H01L 33/06; H01L 25/0753; H01L 33/0083; H01L 2933/0016

(57) ABSTRACT

A light-emitting device is provided. The light-emitting device includes a first electrode, a second electrode, and a quantum dot light-emitting layer and a hole transport doped layer that are located between the first electrode and the second electrode. The hole transport doped layer is located between the quantum dot light-emitting layer and the second electrode. The hole transport doped layer includes a mixture of a first hole transport material and a metal material.

### CROSS-REFERENCE TO RELATED APPLICATION

This application is a bypass continuation application of International Patent Application No. PCT/CN2022/115074, filed on Aug. 26, 2022, which is incorporated herein by reference in its entirety.

### TECHNICAL FIELD

The present disclosure relates to the field of display technologies, and in particular, to a light-emitting device and a method for manufacturing the same, a display panel and a display apparatus.

### BACKGROUND

Quantum dot light-emitting diodes (QLEDs) have received widespread attention in the display field due to their high color gamut, self-luminescence, low turn-on voltage, fast response speed and other advantages. The basic working principle of the quantum dot light-emitting diode is as follows: electrons and holes are injected into both sides of a quantum dot light-emitting layer, and these electrons and holes recombine in the quantum dot light-emitting layer to generate excitons and thus emit light through the excitons.

### SUMMARY

In an aspect, a light-emitting device is provided. The light-emitting device includes a first electrode, a second electrode, and a quantum dot light-emitting layer and a hole transport doped layer located between the first electrode and the second electrode. The hole transport doped layer is located between the quantum dot light-emitting layer and the second electrode. The hole transport doped layer includes a mixture of a first hole transport material and a metal material.

In some embodiments, a mobility of the metal material is greater than a mobility of the first hole transport material.

In some embodiments, a ratio of an equivalent thickness of the metal material to an equivalent thickness of the first hole transport material is in a range of 1:50 to 1:1, inclusive.

In some embodiments, a highest occupied molecular orbital energy level of the first hole transport material is in a range of −5 eV to −7 eV, inclusive.

In some embodiments, the first hole transport material is an organic material.

In some embodiments, a thickness of the hole transport doped layer is in a range of 10 nm to 60 nm, inclusive.

In some embodiments, the light-emitting device further includes a hole injection layer located between the hole transport doped layer and the second electrode, and a work function of the metal material is shallower than a highest occupied molecular orbital energy level of the hole injection layer.

In some embodiments, a work function of the metal material is in a range of −2.2 eV to −4.7 eV, inclusive.

In some embodiments, the light-emitting device layer further includes an electron blocking layer. The electron blocking layer is located between the quantum dot light-emitting layer and the hole transport doped layer. The electron blocking layer includes a second hole transport material, and a lowest unoccupied molecular orbital energy level of the second hole transport material is shallower than a lowest unoccupied molecular orbital energy level of the quantum dot light-emitting layer.

In some embodiments, a thickness of the electron blocking layer is in a range of 5 nm to 50 nm, inclusive.

In some embodiments, a lowest unoccupied molecular orbital energy level of the electron blocking layer is in a range of −2 eV to −3 eV, inclusive.

In some embodiments, the light-emitting device layer further includes an electron transport layer. The electron transport layer is located between the first electrode and the quantum dot light-emitting layer.

In another aspect, a display panel is provided. The display panel includes a substrate and a plurality of light-emitting devices each provided in some of the above embodiments. The plurality of the light-emitting devices are disposed on the substrate.

In yet another aspect, a display apparatus is provided. The display apparatus includes the display panel provided in some of the above embodiments.

In yet another aspect, a method for manufacturing a light-emitting device is provided. The method for manufacturing the light-emitting device includes: forming a quantum dot light-emitting layer on a side of a first electrode; forming a hole transport doped layer on a side of the quantum dot light-emitting layer away from the first electrode, the hole transport doped layer including a mixture of a first hole transport material and a metal material; and forming a second electrode on a side of the hole transport doped layer away from the quantum dot light-emitting layer.

In some embodiments, forming the hole transport doped layer on the side of the quantum dot light-emitting layer away from the first electrode, includes: depositing the first hole transport material and the metal material simultaneously on the side of the quantum dot light-emitting layer away from the first electrode using a dual-source co-evaporation method to form the hole transport doped layer.

In some embodiments, after forming the hole transport doped layer on the side of the quantum dot light-emitting layer away from the first electrode, the method further includes: forming a hole injection layer on the side of the hole transport doped layer away from the quantum dot light-emitting layer, a work function of the metal material being shallower than a highest occupied molecular orbital energy level of the hole injection layer. Forming the second electrode on the side of the hole transport doped layer away from the quantum dot light-emitting layer, includes: forming the second electrode on a side of the hole injection layer away from the quantum dot light-emitting layer.

In some embodiments, after forming the quantum dot light-emitting layer on the side of the first electrode, the method further includes: forming an electron blocking layer on the side of the quantum dot light-emitting layer away from the first electrode, the electron blocking layer including a second hole transport material, and a lowest unoccupied molecular orbital energy level of the second hole transport material being shallower than a lowest unoccupied molecular orbital energy level of the quantum dot light-emitting layer. Forming the hole transport doped layer on the side of the quantum dot light-emitting layer away from the first electrode, includes: forming the hole transport doped layer on a side of the electron blocking layer away from the quantum dot light-emitting layer.

In some embodiments, before forming the quantum dot light-emitting layer on the side of the first electrode, the method further includes: forming an electron transport layer on the side of the first electrode. Forming the quantum dot light-emitting layer on the side of the first electrode, includes: forming the quantum dot light-emitting layer on a side of the electron transport layer away from the first electrode.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a structural diagram of a display panel, in accordance with some embodiments;

FIG. 3 is a sectional view of a display panel, in accordance with some embodiments;

FIG. 4 is a structural diagram of a light-emitting device, in accordance with an implementation;

FIG. 5 is a structural diagram of a light-emitting device, in accordance with some embodiments;

FIG. 6 is a structural diagram of another light-emitting device, in accordance with some embodiments;

FIG. 7 is a structural diagram of another light-emitting device, in accordance with some embodiments;

FIG. 8 is a structural diagram of another light-emitting device, in accordance with some embodiments;

FIG. 9 is a schematic diagram of variation of current efficiency with voltage, in accordance with some embodiments;

FIG. 10 is another schematic diagram of variation of current efficiency with voltage, in accordance with some embodiments;

FIG. 11 is another schematic diagram of variation of current efficiency with voltage, in accordance with some embodiments;

FIG. 12 is another schematic diagram of variation of current efficiency with voltage, in accordance with some embodiments;

FIG. 13 is another schematic diagram of variation of current efficiency with voltage, in accordance with some embodiments;

FIG. 14 is another schematic diagram of variation of current efficiency with voltage, in accordance with some embodiments;

FIG. 15 is a flowchart of a method for manufacturing a light-emitting device, in accordance with some embodiments;

FIG. 16 is a flowchart of a method for manufacturing another light-emitting device, in accordance with some embodiments;

FIG. 17 is a flowchart of a method for manufacturing another light-emitting device, in accordance with some embodiments; and

FIG. 18 is a flowchart of a method for manufacturing another light-emitting device, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “some embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Quantum dot light-emitting diodes (QLEDs) have attracted attention of more and more researchers due to their unique properties such as adjustable luminous color and narrow full width at half maximum, and have been undergone a large number of researches in practical applications.

The basic working principle of the quantum dot light-emitting diode is as follows: electrons and holes are injected into both sides of a quantum dot light-emitting layer, and these electrons and holes recombine in the quantum dot light-emitting layer to generate excitons and thus emit light through the excitons.

However, the unbalanced injection rates of electrons and holes into the quantum dot light-emitting layer may cause the quantum dot light-emitting layer to be in a charged state, so that subsequent electrons and holes undergone non-radiative recombination (auger recombination). Thus, the quantum dot light-emitting diode has a low luminous efficiency.

In the related art, the electron injection efficiency is greater than the hole injection efficiency, which leads to an imbalance in the injection rates of the electrons and the holes into the quantum dot light-emitting layer, thereby resulting in the low luminous efficiency of the quantum dot light-emitting diode.

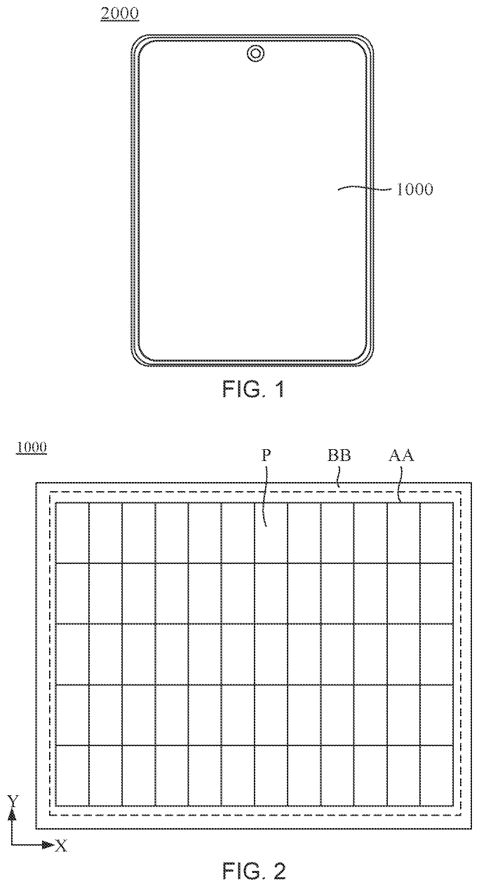

FIG. 1 is a structural diagram of a display apparatus 2000 in accordance with some embodiments.

Referring to FIG. 1, some embodiments of the present disclosure provide a display apparatus 2000. The display apparatus 2000 includes a display panel 1000.

The display apparatus 2000 may be a quantum dot organic light-emitting diode display apparatus, and the corresponding display panel 1000 may be a quantum dot organic light-emitting diode display panel.

FIG. 2 is a structural diagram of a display panel 1000 in accordance with some embodiments.

Referring to FIG. 2, some embodiments of the present disclosure provide a display panel 1000. The display panel 1000 has a display area AA and a peripheral area BB located on at least one side of the display area AA. In some examples, the peripheral area BB is provided around the display area AA.

The display area AA is provided with sub-pixels P of a plurality of colors therein. The sub-pixels P of the plurality of colors at least include a sub-pixel of a first color, a sub-pixel of a second color and a sub-pixel of a third color, and the first color, the second color and the third color may be three primary colors (e.g., red, green and blue). An area of any sub-pixel P may be defined by a pixel defining layer.

For convenience of the description, the plurality of sub-pixels P are described by considering an example where the plurality of sub-pixels P are arranged in an array. In this case, sub-pixels P arranged in a line in a first direction X are referred to as sub-pixels P in a same row, and sub-pixels P arranged in a line in a second direction Y are referred to as sub-pixels P in a same column.

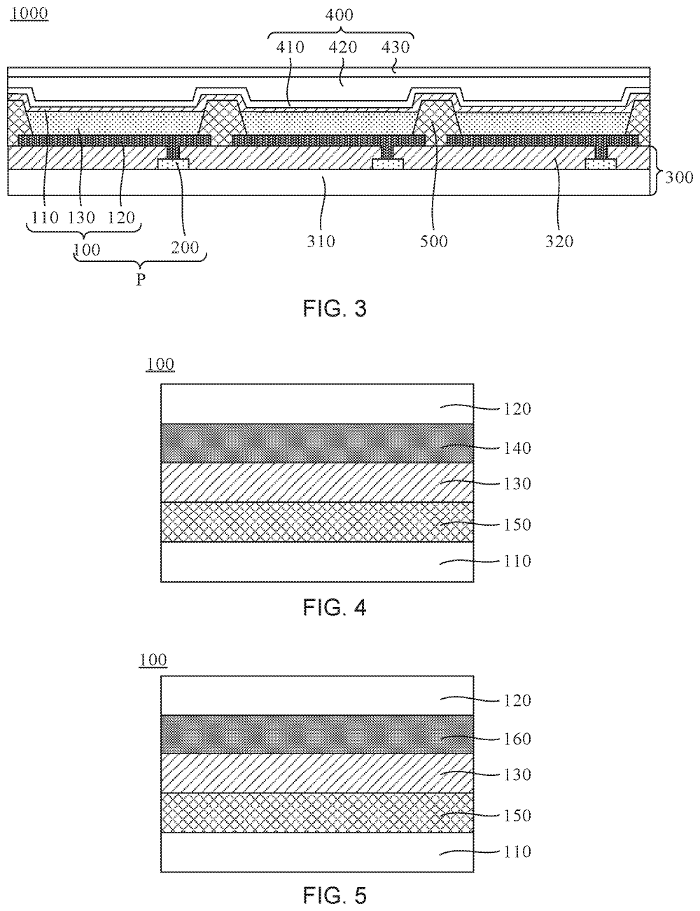

FIG. 3 is a sectional view of a display panel 1000 in accordance with some embodiments.

As shown in FIG. 3, for a single sub-pixel P, the sub-pixel P includes a light-emitting device 100 and a pixel driving circuit 200. The pixel driving circuit 200 is generally composed of thin film transistor(s) (TFT(s)), capacitor(s) (not shown in the figures), and other electronic components. For example, the pixel driving circuit 200 may be a pixel driving circuit composed of two thin film transistors (a switching TFT and a driving TFT) and one capacitor. Of course, the pixel driving circuit 200 may alternatively be a pixel driving circuit composed of two or more thin film transistors (a plurality of switching TFTs and a driving TFT) and at least one capacitor. The pixel driving circuit 200 may include a driving TFT regardless of its structure, and the driving TFT may be electrically connected to an anode of the light-emitting device 100.

The display panel 1000 includes a plurality of film layers. The plurality of film layers in the display panel 1000 are introduced below.

Referring to FIG. 3, the display panel 1000 includes a driving substrate 300, a plurality of light-emitting devices 100 and an encapsulation layer 400 that are stacked in sequence. The plurality of light-emitting devices 100 are provided on a side of the driving substrate 300. The encapsulation layer 400 may protect the plurality of light-emitting devices 100.

The driving substrate 300 includes a substrate 310, pixel driving circuits 200 located on a side of the substrate 310, and an insulating layer 320.

The encapsulation layer 400 includes a first encapsulation film 410, a second encapsulation film 420 and a third encapsulation film 430. In some examples, the first encapsulation film 410 and the third encapsulation film 430 may both be made of inorganic materials. For example, each of the first encapsulation film 410 and the third encapsulation film 430 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride. In some examples, the second encapsulation film 420 may be made of an organic material. For example, the second encapsulation film 420 may be made of acrylic resin, methacrylic resin, polyisoprene, vinyl resin, epoxy resin, ethyl carbamate resin, or cellulosic resin. The lamination structure of the encapsulation layer 400 may be varied.

The plurality of light-emitting devices 100 are disposed on a side of the driving substrate 300, the driving substrate 300 includes the substrate 310, and thus the plurality of light-emitting devices 100 are provided on a side of the substrate 310.

The light-emitting device 100 may include a first electrode 110, a second electrode 120, and a quantum dot light-emitting layer 130 located between the first electrode 110 and the second electrode 120.

In some examples, the first electrode 110 may be a cathode. In this case, the first electrode 110 may provide electrons. Moreover, the second electrode 120 may be an anode. In this case, the second electrode 120 may provide holes.

In some examples, the cathode may be conductive glass. For example, the conductive glass may include materials such as indium tin oxide (ITO) or fluorine-doped tin oxide (FTO). For example, the first electrode 110 may be an ITO substrate. In some examples, a thickness of the first electrode 110 is in a range of 20 nm to 120 nm, inclusive. That is, the thickness of the first electrode 110 is greater than or equal to 20 nm and less than or equal to 120 nm. For example, the thickness of the first electrode 110 is 80 nm.

In some examples, the anode may include materials such as aluminum (Al), silver (Ag), magnesium (Mg), and indium zinc oxide (IZO). A thickness of the second electrode 120 is in a range of 5 nm to 40 nm, inclusive. That is, the thickness of the second electrode 120 is greater than or equal to 5 nm and less than or equal to 40 nm. For example, the thickness of the first electrode 120 is 12 nm.

In some examples, the work function of the second electrode 120 is in a range of −2 eV to −5 eV, inclusive.

In some examples, the anode may also be a mixture of Mg and Ag. For example, a ratio of Mg to Ag may be in a range of 0.1 to 0.4, inclusive.

In some examples, the quantum dot light-emitting layer 130 may include any one or more of the following materials: CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge, and C. The quantum dot light-emitting layer 130 may be a nanoscale material with the above components, such as a nanorod or a nanosheet. In some examples, the quantum dot light-emitting layer 130 does not contain cadmium (Cd).

In some examples, the quantum dot light-emitting layer 130 may be a red quantum dot light-emitting layer, a green quantum dot light-emitting layer, or a blue quantum dot light-emitting layer.

In some examples, a thickness of the quantum dot light-emitting layer 130 may be in a range of 10 nm to 60 nm, inclusive. That is, the thickness of the quantum dot light-emitting layer 130 is greater than or equal to 10 nm and less than or equal to 60 nm. For example, the thickness of the quantum dot light-emitting layer 130 is 30 nm.

In some embodiments, the highest occupied molecular orbital (HOMO) energy level of the quantum dot light-emitting layer 130 is in a range of −5 eV to −7 eV, inclusive, and the lowest unoccupied molecular orbital (LUMO) energy level of the quantum dot light-emitting layer 130 is in a range of −2 eV to −3 eV, inclusive.

In some examples, the first electrode 110 may be located on a side of the second electrode 120 away from the substrate 310. In some other examples, the first electrode 110 may be located between the second electrode 120 and the substrate 310. In the exemplary drawing provided in FIG. 3, the first electrode 110 is located on the side of the second electrode 120 away from the substrate 310.

In addition, the display panel 1000 further includes a pixel defining layer 500. The pixel defining layer 500 is located on a side of the insulating layer 320 away from the substrate 310. The pixel defining layer 500 is provided with a plurality of pixel openings therein, and the quantum dot light-emitting layer 130 may be disposed in a pixel opening.

FIG. 4 is a structural diagram of a light-emitting device 100 in accordance with an implementation.

Referring to FIG. 4, in an implementation, the light-emitting device 100 further includes a hole transport layer (HTL) 140 and an electron transport layer (ETL) 150. The hole transport layer 140 is located between the second electrode 120 and the quantum dot light-emitting layer 130, and the electron transport layer 150 is located between the first electrode 110 and the quantum dot light-emitting layer 130.

The hole transport layer 140 is used to transport holes in the second electrode 120 to the quantum dot light-emitting layer 130. The electron transport layer 150 is used to transport electrons in the first electrode 110 to the quantum dot light-emitting layer 130. The hole transport layer 140 is made of a hole transport material. The hole transport material has a low mobility, and thus the hole transport layer 140 has a low mobility. However, the electron transport layer 150 has a high mobility. As a result, the transmission efficiency of holes is much lower than the transmission efficiency of electrons, which leads to an unbalanced injection of holes and electrons into the quantum dot light-emitting layer 130.

FIG. 5 is a structural diagram of a light-emitting device 100 in accordance with some embodiments.

Referring to FIG. 5, some embodiments of the present disclosure provide a light-emitting device 100. The light-emitting device 100 includes a first electrode 110, a second electrode 120, and a quantum dot light-emitting layer 130 and a hole transport doped layer 160 that are located between the first electrode 110 and the second electrode 120.

The first electrode 110, the second electrode 120 and the quantum dot light-emitting layer 130 have been introduced in some of the above embodiments, and details are not described again here.

The hole transport doped layer 160 is located between the quantum dot light-emitting layer 130 and the second electrode 120. The hole transport doped layer 160 includes a mixture of a first hole transport material and a metal material.

The metal material has good conductivity and a high carrier mobility which is much higher than a carrier mobility of the first hole transport material. Therefore, doping the hole transport doped layer 160 with the metal material may increase the mobility of the hole transport doped layer 160, and further improve the injection efficiency of the holes into the quantum dot light-emitting layer 130, so that the hole injection efficiency and the electron injection efficiency in the quantum dot light-emitting layer 130 may be balanced, thereby improving the luminous efficiency of the quantum dot light-emitting layer 130.

In some embodiments, the mobility of the metal material is greater than the mobility of the first hole transport material. Thus, it may be ensured that the hole transport doped layer 160 has a rather high mobility after being doped with the metal material.

Referring to FIG. 5, the light-emitting device 100 provided by some embodiments of the present disclosure may further include an electron transport layer 150, and the electron transport layer 150 is located between the first electrode 110 and the quantum dot light-emitting layer 130.

The electron transport layer 150 may be a zinc oxide-based nanoparticle film or a zinc oxide film. In addition, in a case where the electron transport layer 150 is the zinc oxide-based nanoparticle film, the material of the electron transport layer 150 may also select ion-doped zinc oxide nanoparticles, such as magnesium-doped (Mg-doped), indium-doped (In-doped), aluminum-doped (Al-doped), or gallium-doped (Ga-doped) zinc oxide nanoparticles.

In some examples, a thickness of the electron transport layer 150 is in a range of 10 nm to 60 nm, inclusive. That is, the thickness of the electron transport layer 150 is greater than or equal to 10 nm and less than or equal to 60 nm. For example, the thickness of the electron transport layer 150 may be 40 nm.

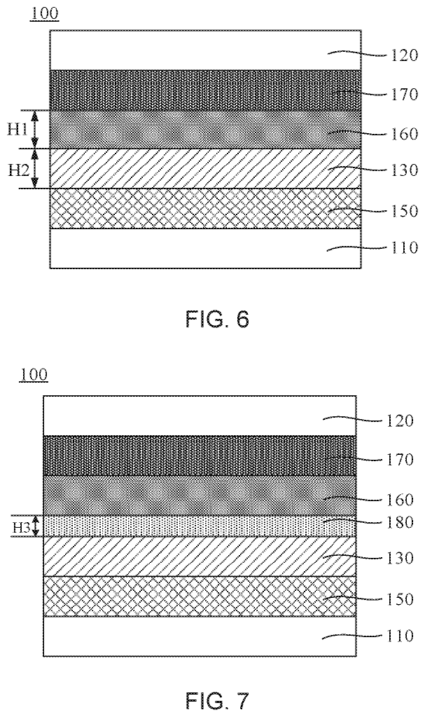

FIG. 6 is a structural diagram of a light-emitting device 100 in accordance with some embodiments.

Referring to FIG. 6, in some embodiments, the light-emitting device 100 further includes a hole injection layer (HIL) 170. The hole injection layer 170 is located between the hole transport doped layer 160 and the second electrode 120. The work function of the metal material is shallower than the highest occupied molecular orbital (HOMO) energy level of the hole injection layer.

The hole injection layer 170 is used to extract electrons and transport the extracted electrons to the second electrode 120. Meanwhile, holes may be formed after the electrons are extracted and transported to the hole transport doped layer 160.

The energy levels of the hole injection layer 170 (including the HOMO energy level and the LUMO energy level) are negative values. The larger the absolute value of the energy level of the hole injection layer 170, the deeper the energy level of the hole injection layer 170. The smaller the absolute value of the energy level of the hole injection layer 170, the shallower the energy level of the hole injection layer 170.

Holes are transported in the highest occupied molecular orbital, while electrons are transported in the lowest unoccupied molecular orbital.

The HOMO energy level of the hole injection layer 170 is deeper than the work function of the metal material. Therefore, holes may spontaneously move from the hole injection layer 170 into the metal material. If the work function of the metal material is deeper than the HOMO energy level of the hole injection layer 170, a barrier between the metal material and the hole injection layer 170 will block movement of the holes, so as to cause a decrease in the amount of the holes moving into the metal material, resulting in a low transmission efficiency of the holes. Therefore, by making the highest occupied molecular orbital energy level of the hole injection layer 170 deeper than the work function of the metal material, the transmission efficiency of the holes may be improved.

In some examples, the material of the hole injection layer 170 may be molybdenum trioxide (MoO₃).

Referring to FIG. 6, in some embodiments, a thickness H1 of the hole transport doped layer 160 is 0.16 times to 6 times a thickness H2 of the quantum dot light-emitting layer 130, that is, 0.16×H2≤H1≤6×H2.

During manufacturing the light-emitting device 100, the first electrode 110 will be formed first. The first electrode 110 may be of a plate-like structure, and spikes may be formed on the first electrode 110. Then, the electron transport layer 150, the quantum dot light-emitting layer 130, the hole transport doped layer 160 and the second electrode 120 in the light-emitting device 100 are sequentially formed on the first electrode 110. In the above embodiments of the present disclosure, setting the thickness H1 of the hole transport doped layer 160 greater than or equal to 0.16 times the thickness H2 of the quantum dot light-emitting layer 130 (i.e., H1≥0.16×H2) may avoid an excessively small thickness H1 (e.g., less than 0.16×H2) of the hole transport doped layer 160, so as to prevent the hole transport doped layer 160 from being punctured by the spikes on the first electrode 110, thereby reducing leakage of the hole transport doped layer 160 caused by being punctured.

In addition, setting the thickness H1 of the hole transport doped layer 160 less than or equal to 6 times the thickness H2 of the quantum dot light-emitting layer 130 (i.e., H1≤6×H2) may avoid difficulty for holes to pass through the hole transport doped layer 160 caused by an excessively large thickness H1 (e.g., greater than 6×H2) of the hole transport doped layer 160.

In some embodiments, the thickness H1 of the hole transport doped layer 160 is in a range of 10 nm to 60 nm, inclusive, that is, 10 nm≤H1≤60 nm.

The thickness H1 of the hole transport doped layer 160 is set greater than or equal to 10 nm (i.e., H1≥10 nm), so that the thickness H1 of the hole transport doped layer 160 may be prevented from being excessively small (e.g., less than 10 nm), so as to prevent the hole transport doped layer 160 from being punctured by the spikes on the first electrode 110, thereby reducing leakage of the hole transport doped layer 160 caused by being punctured.

In addition, the thickness H1 of the hole transport doped layer 160 is set less than or equal to 60 nm (i.e., H1≤60 nm), thereby avoiding difficulty for holes to pass through the hole transport doped layer 160 caused by an excessively large thickness H1 (e.g., greater than 60 nm) of the hole transport doped layer 160.

In some embodiments, the first hole transport material may be an organic material. For example, the organic material may be formed into a film by evaporation. The film formed by evaporation has good uniformity and a controllable process, and is suitable for large-area film formation. Correspondingly, the metal material is also formed into the hole transport doped layer 160 by evaporation. Therefore, in some embodiments of the present disclosure, the provided hole transport doped layer 160 has good film formation uniformity, a controllable process, and may be suitable for large-area film formation.

For example, the first hole transport material and the metal material may be formed into a film (i.e., the hole transport doped layer 160) by evaporation. Since a film layer formed by evaporating the metal material during co-evaporation is relatively thin, the metal material generally has an island structure. Therefore, after the first hole transport material and the metal material are co-evaporated, the metal material is uniformly distributed in the hole transport doped layer 160 in granular shapes. Since the first hole transport material used for evaporation is evaporated into a film after being heated, the first hole transport material that can be used for evaporation itself must have good stability and will not thermally decompose or undergone chemically react under heat effect. Therefore, no chemical reaction occurs after co-evaporation with the metal.

In some embodiments, the first hole transport material may be carbazole, triphenylamine, carbazole derivatives, triphenylamine derivatives, and other materials.

In some examples, the first hole transport material includes any of NPB, CBP, BCBP and NPD.

In some other embodiments, the first hole transport material may be a nano-inorganic substance. The nano-inorganic substance has relatively high stability. In this case, the first hole transport material may be formed into a film by sputtering.

In some embodiments, the work function of the metal material is in a range of −2.2 eV to −4.7 eV, inclusive. That is, the work function of the metal material is greater than or equal to −4.7 eV and less than or equal to −2.2 eV.

When holes are transported from the hole injection layer 170 to the first hole transport material, if the absolute value of the HOMO energy level of the first hole transport material is greater than the absolute value of the work function of the metal material, the greater the difference between the absolute value of the HOMO energy level of the first hole transport material and the absolute value of the work function of the metal material, the more conducive it is to the transport of holes.

Making the work function of the metal material greater than or equal to −4.7 eV may prevent the work function of the metal material from being excessively deep and deeper than the HOMO energy level of the hole injection layer 170, thereby preventing the barrier between the metal material and the hole injection layer 170 from blocking the transport of holes, and avoiding reducing the hole transmission efficiency.

In a case where the work function of the metal material is close to −2.2 eV, it can be considered that the hole injection layer 170 and the metal material have a relatively large barrier therebetween. Then, when holes are transported from the hole injection layer 170 to the metal material, the larger the barrier between the hole injection layer 170 and the metal material, the more conducive it is to the transport of holes.

In some embodiments, the metal material may be any of magnesium (Mg), silver (Ag), and aluminum (Al).

For example, the metal material may be Mg, and Mg has a relatively low evaporation temperature, good activity, and high conductivity.

In some examples, the highest occupied molecular orbital (HOMO) energy level of the first hole transport material is deeper than the work function of the metal material. That is, the absolute value of the highest occupied molecular orbital (HOMO) energy level of the first hole transport material is greater than the absolute value of the work function of the metal material.

In some examples, the highest occupied molecular orbital (HOMO) energy level of the first hole transport material is shallower than the HOMO energy level of the hole injection layer 170, and thus holes may spontaneously move from the hole injection layer 170 into the first hole transport material, thereby improving transmission efficiency of holes.

In some embodiments, the highest occupied molecular orbital (HOMO) energy level of the first hole transport material is in a range of −5 eV to −7 eV, inclusive.

When holes are transported from the hole injection layer 170 to the first hole transport material, if the HOMO energy level of the first hole transport material is shallower than the HOMO energy level of the hole injection layer 170, the larger the barrier between the first hole transport material and the hole injection layer 170, the more conducive it is to the transport of holes.

In some embodiments of the present disclosure, the highest occupied molecular orbital (HOMO) energy level of the first hole transport material is made greater than or equal to −7 eV, thus it may avoid affecting the transmission efficiency of holes due to blocking of transport of holes by the barrier between the first hole transport material and the hole injection layer 170, which is caused by the energy level of the first hole transport material deeper than the HOMO energy level of the hole injection layer 170 due to an excessively deep highest occupied molecular orbital (HOMO) energy level of the first hole transport material.

In addition, the highest occupied molecular orbital (HOMO) energy level of the first hole transport material is made less than or equal to −5 eV, thus it may avoid a decrease in transmission efficiency of holes caused by a large barrier due to a large difference between the HOMO energy level of the first hole transport material and the HOMO energy level of the quantum dot light-emitting layer 130, which is caused by an excessive shallow highest occupied molecular orbital (HOMO) energy level of the first hole transport material. Therefore, making the highest occupied molecular orbital (HOMO) energy level of the first hole transport material less than or equal to −5 eV may ensure the transmission efficiency of holes.

In some examples, the HOMO energy level of the hole transport doped layer 160 is shallower than the HOMO energy level of the quantum dot light-emitting layer 130.

In some other examples, the HOMO energy level of the hole transport doped layer 160 may be equal to the HOMO energy level of the quantum dot light-emitting layer 130.

In some embodiments, the mobility of the first hole transport material is in a range of 10⁻⁴ cm²V⁻¹S⁻¹ to 10⁻² cm²V⁻¹S⁻¹, inclusive.

FIG. 7 is a structural diagram of a light-emitting device 100 in accordance with some embodiments.

Referring to FIG. 7, in some embodiments, the light-emitting device 100 further includes an electron blocking layer (EBL) 180. The electron blocking layer 180 is located between the quantum dot light-emitting layer 130 and the hole transport doped layer 160. The electron blocking layer 180 includes a second hole transport material, and the lowest unoccupied molecular orbital (LUMO) energy level of the second hole transport material is shallower than the lowest unoccupied molecular orbital energy level of the quantum dot light-emitting layer 130. Therefore, the lowest unoccupied molecular orbital (LUMO) energy level of the electron blocking layer 180 is shallower than the lowest unoccupied molecular orbital (LUMO) energy level of the quantum dot light-emitting layer 130.

Since the lowest unoccupied molecular orbital (LUMO) energy level of the second hole transport material is shallower than the lowest unoccupied molecular orbital (LUMO) energy level of the quantum dot light-emitting layer 130, a barrier may be formed between the electron blocking layer 180 and the quantum dot light-emitting layer 130, and thus the electrons are difficult to move from the quantum dot light-emitting layer 130 to the electron blocking layer 180, thereby blocking the electrons in the quantum dot light-emitting layer 130. Therefore, it may avoid a decrease in luminous efficiency of the quantum dot light-emitting layer 130 caused by loss of electrons in the quantum dot light-emitting layer 130.

In some embodiments, the second hole transport material may be carbazole, triphenylamine, carbazole derivatives, triphenylamine derivatives, and other materials.

In some examples, the second hole transport material includes any of NPB, CBP, BCBP, and NPD.

In some embodiments, referring to FIG. 7, a thickness H3 of the electron blocking layer 180 is 0.083 times to 5 times the thickness H2 of the quantum dot light-emitting layer 130, that is, 0.083×H2≤H3≤5×H2.

Setting the thickness H3 of the electron blocking layer 180 greater than or equal to 0.083 times the thickness H2 of the of the quantum dot light-emitting layer 130 (i.e., H3≥0.083×H2) may prevent the electron blocking layer 180 from being punctured by the spikes on the first electrode 110, thereby reducing leakage of the electron blocking layer 180 caused by being punctured.

In addition, setting the thickness H3 of the electron blocking layer 180 less than or equal to 5 times the thickness H2 of the of the quantum dot light-emitting layer 130 (i.e., H3≤5×H2) may avoid difficulty for holes to pass through the electron blocking layer 180 caused by an excessively large thickness H3 (e.g., greater than 5×H2) of the electron blocking layer 180.

In some examples, the thickness H3 of the electron blocking layer 180 is less than the thickness H1 of the hole transport doped layer 160.

In some embodiments, the thickness H3 of the electron blocking layer 180 is in a range of 5 nm to 50 nm, inclusive. That is, 5 nm≤H3≤50 nm.

Setting the thickness H3 of the electron blocking layer 180 greater than or equal to 5 nm (i.e., H3≥5 nm) may prevent the thickness H3 of the electron blocking layer 180 from being excessively small (e.g., less than 5 nm), so as to prevent the electron blocking layer 180 from being punctured by the spikes on the first electrode 110, thereby reducing leakage of the electron blocking layer 180 caused by being punctured.

In addition, setting the thickness H3 of the electron blocking layer 180 less than or equal to 50 nm (i.e., H3≤50 nm) may avoid difficulty for holes to pass through the electron blocking layer 180 caused by an excessively large thickness H3 (e.g., greater than 50 nm) of the electron blocking layer 180.

In some embodiments, the lowest unoccupied molecular orbital (LUMO) energy level of the electron blocking layer 180 is in a range of −2 eV to −3 eV, inclusive. That is, the lowest unoccupied molecular orbital (LUMO) energy level of the electron blocking layer 180 is greater than or equal to −3 eV and less than or equal to −2 eV.

The lowest unoccupied molecular orbital (LUMO) energy level of the electron blocking layer 180 is made less than or equal to −2 eV, thereby avoiding inability to block electrons in the quantum dot light-emitting layer 130 caused by an excessively small barrier between the quantum dot light-emitting layer 130 and the electron blocking layer 180 due to an excessively shallow LUMO energy level of the electron blocking layer 180.

The lowest unoccupied molecular orbital (LUMO) energy level of the electron blocking layer 180 is made greater than or equal to −3 eV, thereby prevent the LUMO energy level of the electron blocking layer 180 from being excessively deep.

In some examples, the highest occupied molecular orbital (HOMO) energy level of the second hole transport material is shallower than the highest occupied molecular orbital (HOMO) energy level of the first hole transport material.

In some examples, the HOMO energy level of the electron blocking layer 180 is shallower than the HOMO energy level of the quantum dot light-emitting layer 130.

In some other examples, the HOMO energy level of the electron blocking layer 180 is equal to the HOMO energy level of the quantum dot light-emitting layer 130.

In some embodiments, the highest occupied molecular orbital (HOMO) energy level of the electron blocking layer 180 is in a range of −5 eV to −7 eV, inclusive. That is, the HOMO energy level of the second hole transport material is in a range of −5 eV to −7 eV, inclusive. Therefore, the HOMO energy level of the second hole transport material and the HOMO energy level of the first hole transport material may have a relatively small difference, that is, the barrier between the second hole transport material and the first hole transport material is relatively small.

In some embodiments, the mobility of the electron blocking layer 180 is in a range of 10⁻³ cm²V⁻¹S⁻¹ to 10⁻⁵ cm²V⁻¹S⁻¹, inclusive. That is, the mobility of the second hole transport material is in a range of 10⁻³ cm²V⁻¹S⁻¹ to 10⁻⁵ cm²V⁻¹S⁻¹, inclusive.

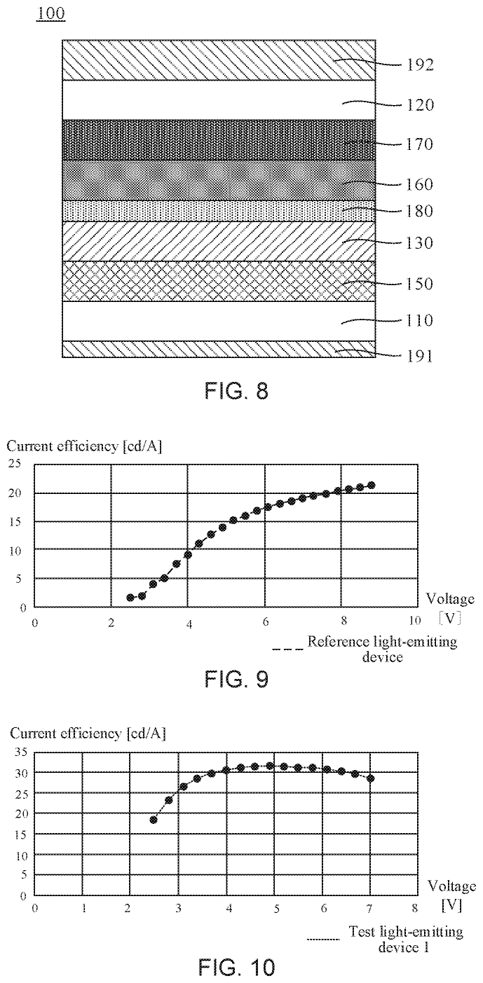

FIG. 8 is a structural diagram of a light-emitting device 100 in accordance with some embodiments.

Referring to FIG. 8, in some examples, the light-emitting device 100 further includes a reflective layer 191, and the reflective layer 191 is located on a side of the first electrode 110 away from the quantum dot light-emitting layer 130. By providing the reflective layer 191, the light-emitting device 100 may emit light from a single side. Moreover, the reflective layer 191 may reflect light irradiated onto the reflective layer 191, so that more light can exit from a light-exit side of the light-emitting device 100, thereby improving the luminous efficiency of the light-emitting device 100.

In some examples, the light-emitting device 100 further includes a light extraction layer 192, and the light extraction layer 192 is located on a side of the second electrode 120 away from the quantum dot light-emitting layer 130. The light extraction layer 192 is used to increase the light extraction rate of the light-emitting device 100.

In some embodiments, in the hole transport doped layer 160, a ratio of an equivalent thickness of the metal material to an equivalent thickness of the first hole transport material is in a range of 1:50 to 1:1, inclusive. That is, the equivalent thickness of the metal material is 0.02 to 1 times the equivalent thickness of the first hole transport material.

A total amount of the metal material in the hole transport doped layer 160 is a first set amount, and an area of the quantum dot light-emitting layer 130 in the light-emitting device 100 is a first set area. When the metal material with the first set amount is evaporated separately on the quantum dot light-emitting layer 130 with the first set area, a thickness of the film layer formed by the metal material is the equivalent thickness of the metal material in the hole transport doped layer 160.

A total amount of the first hole transport material in the hole transport doped layer 160 is a second set amount, and the area of the quantum dot light-emitting layer 130 in the light-emitting device 100 is the first set area. When the first hole transport material with the second set amount is evaporated separately on the quantum dot light-emitting layer 130 with the first set area, a thickness of the film layer formed by the first hole transport material is the equivalent thickness of the first hole transport material in the hole transport doped layer 160.

In some of the above embodiments of the present disclosure, the equivalent thickness of the metal material is set greater than or equal to 0.02 times the equivalent thickness of the first hole transport material, so that the equivalent thickness of the metal material may be prevented from being excessively small (e.g., smaller than 0.02 times the equivalent thickness of the first hole transport material), thereby avoiding an excessively small mobility of the hole transport doped layer 160 due to an excessively little metal material in the hole transport doped layer 160. Therefore, making the equivalent thickness of the metal material greater than or equal to 0.02 times the equivalent thickness of the first hole transport material may ensure a great mobility of the hole transport doped layer 160.

In addition, the work function of the metal material is shallower than the HOMO energy level of the first hole transport material, and the work function of the metal material is shallower than the HOMO energy level of the quantum dot light-emitting layer 130. Therefore, there is a relatively small difference between the HOMO energy level of the first hole transport material and the HOMO energy level of the quantum dot light-emitting layer 130, which makes them more consistent.

In some of the above embodiments of the present disclosure, the equivalent thickness of the metal material is set less than or equal to 1 times the equivalent thickness of the first hole transport material, so that the equivalent thickness of the metal material may be prevented from being excessively large (e.g., larger than 1 times the equivalent thickness of the first hole transport material), thereby avoiding a low transmission efficiency of holes caused by a relatively large barrier, which is caused by a relatively large energy level difference between the hole transport doped layer 160 and the quantum dot light-emitting layer 130 due to excessively much metal material in the hole transport doped layer 160. Therefore, in some embodiments of the present disclosure, making the equivalent thickness of the metal material less than or equal to 1 times the equivalent thickness of the first hole transport material may avoid an excessively large energy level difference between the hole transport doped layer 160 and the quantum dot light-emitting layer 130, thereby ensuring the transmission efficiency of holes.

In some examples, in the hole transport doped layer 160, the ratio of the equivalent thickness of the metal material to the equivalent thickness of the first hole transport material is in a range of 1:10 to 1:50, inclusive.

For example, in the hole transport doped layer 160, the ratio of the equivalent thickness of the metal material to the equivalent thickness of the first hole transport material is 1:40.

In embodiments of the present disclosure, a reference light-emitting device, a test light-emitting device 1, a test light-emitting device 2, a test light-emitting device 3, and a test light-emitting device 4 are tested.

The reference light-emitting device includes a reflective layer 191, a first electrode 110, an electron transport layer 150, a quantum dot light-emitting layer 130, an electron blocking layer 180, a hole transport layer 140, a hole injection layer 170, a second electrode 120 and a light extraction layer 192 that are stacked in sequence.

In the reference light-emitting device, the first electrode 110 is an ITO substrate and has a thickness of 80 nm. The electron transport layer 150 is made of ZnO and has a thickness of 40 nm. The quantum dot light-emitting layer 130 is a red quantum dot light-emitting layer and has a thickness of 30 nm. The second hole transport material in the electron blocking layer 180 is BCBP, and the electron blocking layer 180 has a thickness of 10 nm. The hole injection layer 170 is made of MoO₃ and has a thickness of 7 nm. The second electrode 120 includes a mixture of Mg and Ag, a mixing ratio of Mg to Ag is 3:7, and the second electrode 120 has a thickness of 12 nm. The light extraction layer 192 has a thickness of 70 nm.

In the reference light-emitting device, the hole transport layer 140 includes NPD and has a thickness of 30 nm. In the reference light-emitting device, the hole transport layer 140 does not include a metal material, that is, the doped ratio of the metal material is 0.

The current efficiency schematic diagram shown in FIG. 9 can be obtained after the reference light-emitting device is tested. It can be seen from FIG. 9 that in a case where the hole transport layer 140 is not doped with the metal material, the maximum current efficiency of the reference light-emitting device 100 is about 22 cd/A.

The test light-emitting device 1 includes a reflective layer 191, a first electrode 110, an electron transport layer 150, a quantum dot light-emitting layer 130, an electron blocking layer 180, a hole transport doped layer 160, a hole injection layer 170, a second electrode 120 and a light extraction layer 192 that are stacked in sequence.

In the test light-emitting device 1, except for the hole transport doped layer 160, materials and thicknesses of other structures are the same as those of the reference light-emitting device.

In the test light-emitting device 1, in the hole transport doped layer 160, the first hole transport material is NPD, the metal material is Mg, a ratio of an equivalent thickness of Mg to an equivalent thickness of NPD is 1:10, and the hole transport doped layer 160 has a thickness of 30 nm.

The current efficiency schematic diagram shown in FIG. 10 can be obtained after the test light-emitting device 1 is tested. It can be seen from FIG. 10 that in a case where the ratio of the equivalent thicknesses of the metal material and the first hole transport material in the hole transport doped layer 160 is 1:10, the maximum current efficiency of the test light-emitting device 1 is about 32 cd/A.

The test light-emitting device 2 includes a reflective layer 191, a first electrode 110, an electron transport layer 150, a quantum dot light-emitting layer 130, an electron blocking layer 180, a hole transport doped layer 160, a hole injection layer 170, a second electrode 120 and a light extraction layer 192 that are stacked in sequence.

In the test light-emitting device 2, except for the hole transport doped layer 160, materials and thicknesses of other structures are the same as those of the reference light-emitting device.

In the test light-emitting device 2, in the hole transport doped layer 160, the first hole transport material is NPD, the metal material is Mg, a ratio of an equivalent thickness of Mg to an equivalent thickness of NPD is 1:20, and the hole transport doped layer 160 has a thickness of 30 nm.

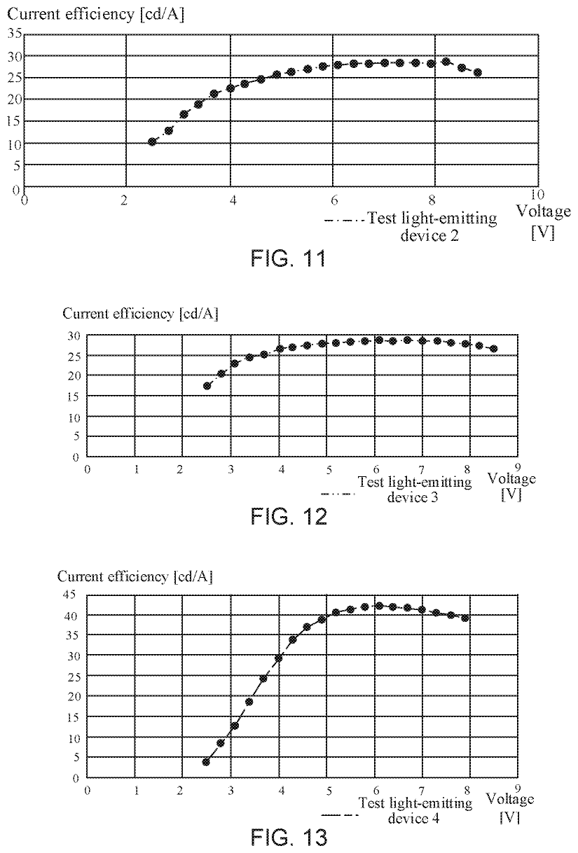

The current efficiency schematic diagram shown in FIG. 11 can be obtained after the test light-emitting device 2 is tested. It can be seen from FIG. 11 that in a case where the ratio of the equivalent thicknesses of the metal material and the first hole transport material in the hole transport doped layer 160 is 1:20, the maximum current efficiency of the test light-emitting device 2 is about 30 cd/A.

The test light-emitting device 3 includes a reflective layer 191, a first electrode 110, an electron transport layer 150, a quantum dot light-emitting layer 130, an electron blocking layer 180, a hole transport doped layer 160, a hole injection layer 170, a second electrode 120 and a light extraction layer 192 that are stacked in sequence.

In the test light-emitting device 3, except for the hole transport doped layer 160, materials and thicknesses of other structures are the same as those of the reference light-emitting device.

In the test light-emitting device 3, in the hole transport doped layer 160, the first hole transport material is NPD, the metal material is Mg, a ratio of an equivalent thickness of Mg to an equivalent thickness of NPD is 1:30, and the hole transport doped layer 160 has a thickness of 30 nm.

The current efficiency schematic diagram shown in FIG. 12 can be obtained after the test light-emitting device 3 is tested. It can be seen from FIG. 12 that in a case where the ratio of the equivalent thicknesses of the metal material and the first hole transport material in the hole transport doped layer 160 is 1:30, the maximum current efficiency of the test light-emitting device 3 is about 30 cd/A.

The test light-emitting device 4 includes a reflective layer 191, a first electrode 110, an electron transport layer 150, a quantum dot light-emitting layer 130, an electron blocking layer 180, a hole transport doped layer 160, a hole injection layer 170, a second electrode 120 and a light extraction layer 192 that are stacked in sequence.

In the test light-emitting device 4, except for the hole transport doped layer 160, materials and thicknesses of other structures are the same as those of the reference light-emitting device.

In the test light-emitting device 4, in the hole transport doped layer 160, the first hole transport material is NPD, the metal material is Mg, a ratio of an equivalent thickness of Mg to an equivalent thickness of NPD is 1:40, and the hole transport doped layer 160 has a thickness of 30 nm.

The current efficiency schematic diagram shown in FIG. 13 can be obtained after the test light-emitting device 4 is tested. It can be seen from FIG. 13 that in a case where the ratio of the equivalent thicknesses of the metal material and the first hole transport material in the hole transport doped layer 160 is 1:40, the maximum current efficiency of the test light-emitting device 4 is about 41 cd/A.

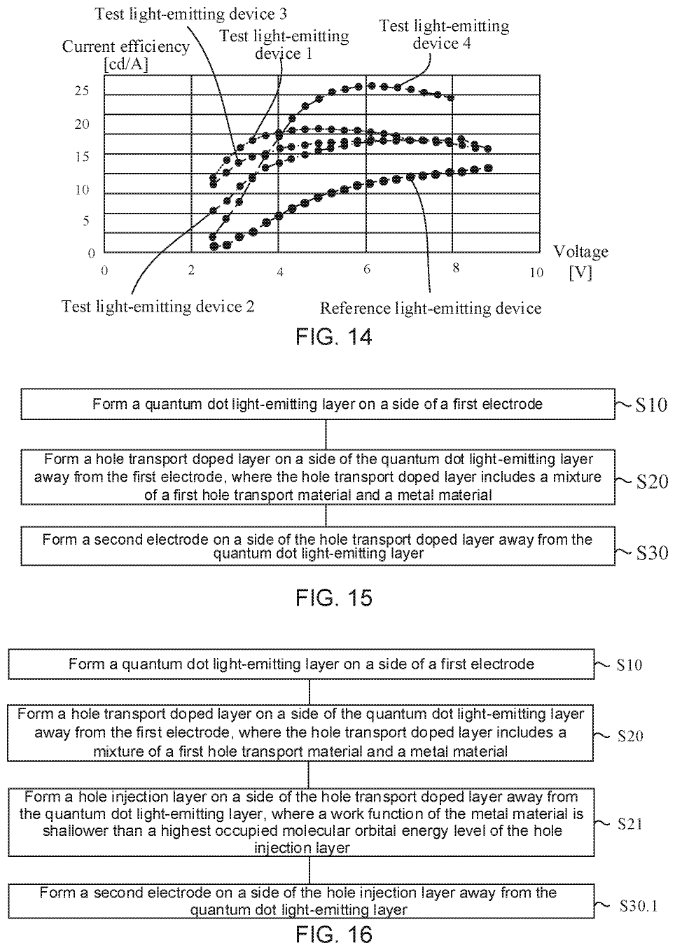

Then, the current efficiency schematic diagrams of the reference light-emitting device, the test light-emitting device 1, the test light-emitting device 2, the test light-emitting device 3 and the test light-emitting device 4 respectively shown in FIGS. 9 to 13 are summarized in the same figure. As shown in FIG. 14, the current efficiency of any test light-emitting device is greater than that of the reference light-emitting device.

To sum up, the maximum current efficiencies of the test light-emitting device 1, the test light-emitting device 2, the test light-emitting device 3 and the test light-emitting device 4 are all greater than the maximum current efficiency of the reference light-emitting device. The greater the current efficiency, the higher the luminous efficiency of the light-emitting device. Therefore, it can be proved from FIGS. 9 to 14 that providing the hole transport doped layer 160 in the light-emitting device 100 may improve transmission efficiency of holes of the light-emitting device 100, so that injection of holes and electrons in the quantum dot light-emitting layer 130 may be rather balanced, thereby improving the luminous efficiency of the light-emitting device 100.

The display panel 1000 provided in some embodiments of the present disclosure includes the light-emitting device 100 provided in some of the above embodiments. Therefore, the display panel 1000 provided in some embodiments of the present disclosure has all the beneficial effects of the light-emitting device 100 provided in some of the above embodiments, and details are not repeated here.

The display apparatus 2000 provided in some embodiments of the present disclosure includes the display panel 1000 provided in some of the above embodiments. Therefore, the display apparatus 2000 provided in some embodiments of the present disclosure has all the beneficial effects of the display panel 1000 provided in some of the above embodiments, and details are not repeated here.

Some embodiments of the present disclosure provide a method for manufacturing a light-emitting device, which is used in light-emitting device 100 provided in some of the above embodiments.

FIG. 15 is a flowchart of a method for manufacturing a light-emitting device in accordance with some embodiments.

With reference to FIG. 15, the method for manufacturing the light-emitting device includes following steps S10 to S30.

In S10, a quantum dot light-emitting layer 130 is formed on a side of a first electrode 110.

With reference to FIG. 5 again, the first electrode 110 may be conductive glass. For example, the first electrode 110 may be an ITO substrate.

The quantum dot light-emitting layer 130 may be formed on the ITO substrate by spin coating. For example, the quantum dot light-emitting material solution is applied on a side of the cleaned ITO substrate by spin coating, and then annealing is performed in a nitrogen atmosphere, where the temperature of annealing may be in a range of 80° C. to 180° C., inclusive.

In S20, a hole transport doped layer 160 is formed on a side of the quantum dot light-emitting layer 130 away from the first electrode 110, and the hole transport doped layer 160 includes a mixture of a first hole transport material and a metal material.

The carrier mobility of the metal material is relatively high and much higher than the carrier mobility of the first hole transport material. Therefore, the mobility of the hole transport doped layer 160 may be increased, and the injection efficiency of the holes into the quantum dot light-emitting layer 130 may further be improved. As a result, the hole injection efficiency and the electron injection efficiency in the quantum dot light-emitting layer 130 may be balanced, thereby improving the luminous efficiency of the quantum dot light-emitting layer 130.

For example, the hole transport doped layer 160 may be formed by evaporation. After the quantum dot light-emitting layer 130 is formed into a film, the ITO substrate covered with the quantum dot light-emitting layer 130 may be transferred to an evaporator, with evacuated to less than 10⁻⁶ torr, and then the first hole transport material and the metal material may be evaporated.

When the hole transport doped layer 160 is formed by evaporation, film layer(s) (e.g., the quantum dot light-emitting layer 130) formed before the hole transport doped layer 160 will not be subjected to a significant impact, so as to prevent the film layer(s) formed before the hole transport doped layer 160 from being damaged due to the impact. In addition, the hole transport doped layer 160 formed by evaporation has a uniform thickness and facilitates large-scale film formation.

In some other embodiments, the hole transport doped layer 160 may be formed by spin coating.

In some embodiments, in the step S20 of forming the hole transport doped layer 160 on the side of the quantum dot light-emitting layer 130 away from the first electrode 110, the first hole transport material and the metal material are simultaneously deposited on the side of the quantum dot light-emitting layer 130 away from the first electrode 110 using a dual-source co-evaporation method to form the hole transport doped layer 160.

The “dual-source co-evaporation method” refers to providing two evaporation sources in the coating chamber, one of the evaporation sources is used to evaporate the first hole transport material, and the other of the evaporation sources is used to evaporate the metal material.

When the hole transport doped layer 160 is formed by dual-source co-evaporation, the metal material may be uniformly distributed in the hole transport doped layer 160.

In S30, a second electrode 120 is formed on a side of the hole transport doped layer 160 away from the quantum dot light-emitting layer 130.

The second electrode 120 may be a film layer made of a mixture of Mg and Ag, and the second electrode 120 may be formed by evaporation.

When the second electrode 120 is formed by evaporation, film layer(s) (e.g., the hole transport doped layer 160) formed before the second electrode 120 will not be subjected to an impact, so as to prevent the film layer(s) formed before the second electrode 120 from being damaged due to the impact. In addition, the second electrode 120 formed by evaporation has a good film formation uniformity and is suitable for large-area film formation.

FIG. 16 is a flowchart of a method for manufacturing a light-emitting device in accordance with some embodiments.

Referring to FIG. 16, in some embodiments, after the step S20, the method for manufacturing the light-emitting device further includes a step S21, and the step S30 may include a step S30.1.

With reference to FIG. 6 again, after the step S20 of forming the hole transport doped layer 160 on the side of the quantum dot light-emitting layer 130 away from the first electrode 110, the method further includes a step S21: forming a hole injection layer 170 on a side of the hole transport doped layer 160 away from the quantum dot light-emitting layer 130. The work function of the metal material is shallower than the highest occupied molecular orbital energy level of the hole injection layer 170.

Accordingly, the step S30 of forming the second electrode 120 on the side of the hole transport doped layer 160 away from the quantum dot light-emitting layer 130 includes a step S30.1: forming the second electrode 120 on a side of the hole injection layer 170 away from the quantum dot light-emitting layer 130.

In some examples, the hole injection layer 170 may be formed by evaporation. When the hole injection layer 170 is formed by evaporation, the hole transport doped layer 160 will not be subjected to an impact, so as to reduce probability of the hole transport doped layer 160 being damaged due to the impact. Moreover, the hole injection layer 170 formed by evaporation has good film formation uniformity and is suitable for large-scale film formation.

In some other examples, the hole transport doped layer 160 may be formed by spin coating or sputtering.

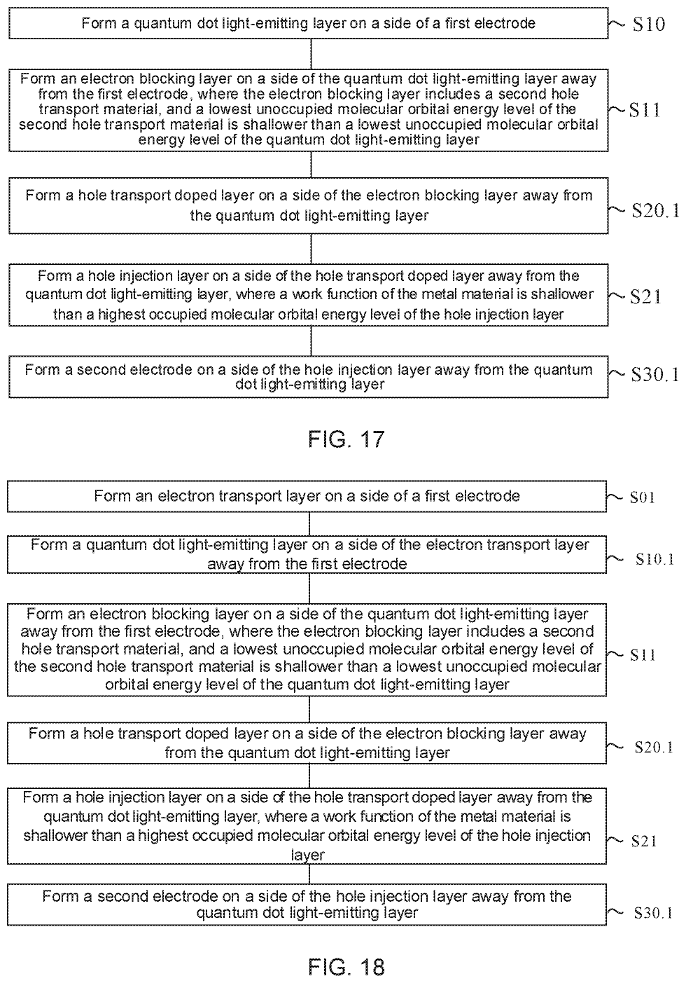

FIG. 17 is a flowchart of a method for manufacturing a light-emitting device in accordance with some embodiments.

Referring to FIG. 17, after the step S10, the method for manufacturing the light-emitting device further includes a step S11, and accordingly, the step S20 may include a step S20.1.

With reference to FIG. 7 again, in some embodiments, after the step S10 of forming the quantum dot light-emitting layer 130 on the side of the first electrode 110, the method further includes a step S11: forming an electron blocking layer 180 on a side of the quantum dot light-emitting layer 130 away from the first electrode 110. The electron blocking layer 180 includes a second hole transport material, and the lowest unoccupied molecular orbital (LUMO) energy level of the second hole transport material is shallower than the lowest unoccupied molecular orbital (LUMO) energy level of the quantum dot light-emitting layer 130.

Accordingly, the step S20 of forming the hole transport doped layer 160 on the side of the quantum dot light-emitting layer 130 away from the first electrode 110 includes a step S20.1: forming the hole transport doped layer 160 on a side of the electron blocking layer 180 away from the quantum dot light-emitting layer 130.

Since the lowest unoccupied molecular orbital (LUMO) energy level of the second hole transport material is shallower than the lowest unoccupied molecular orbital (LUMO) energy level of the quantum dot light-emitting layer 130, a barrier may be formed between the electron blocking layer 180 and the quantum dot light-emitting layer 130, and thus the electrons are difficult to move from the quantum dot light-emitting layer 130 to the electron blocking layer 180, thereby blocking the electrons in the quantum dot light-emitting layer 130, and avoiding a decrease in luminous efficiency of the quantum dot light-emitting layer 130 caused by loss of electrons in the quantum dot light-emitting layer 130.

In some examples, the second hole transport material may be formed on the side of the quantum dot light-emitting layer 130 by evaporation, thereby forming the electron blocking layer 180.

When the electron blocking layer 180 is formed by evaporation, the quantum dot light-emitting layer 130 will not be subjected to an impact, so as to reduce probability of the quantum dot light-emitting layer 130 being damaged due to the impact. Moreover, the electron blocking layer 180 formed by evaporation has good film formation uniformity and is suitable for large-scale film formation.

In some other examples, the electron blocking layer 180 may be formed by spin coating or sputtering.

FIG. 18 is a flowchart of a method for manufacturing a light-emitting device in accordance with some embodiments.

Referring to FIG. 18, before the step S10, the method for manufacturing the light-emitting device may further include a step S01, and accordingly, the step S10 includes a step S10.1.

With reference to FIG. 6 again, in some embodiments, before the step S10 of forming the quantum dot light-emitting layer 130 on the side of the first electrode 110, the method further includes a step S01: forming an electron transport layer 150 on the side of the first electrode 110. Accordingly, the step S10 of forming the quantum dot light-emitting layer 130 on the side of the first electrode 110 includes a step S10.1: forming the quantum dot light-emitting layer 130 on a side of the electron transport layer 150 away from the first electrode 110.

In some examples, the electron transport layer 150 may be formed by spin coating. For example, in a case where the electron transport layer 150 includes ZnO, a ZnO solution may be applied on the ITO substrate by spin coating, and then annealing is performed in a nitrogen atmosphere, where the temperature of annealing may be in a range of 80° C. to 180° C., inclusive; then, the quantum dot light-emitting material may be continuously applied on the ZnO film by spin coating to form the quantum dot light-emitting layer 130.

Referring to FIG. 8, in some examples, a reflective layer 191 is further formed on another side of the first electrode 110. In this case, the reflective layer 191 may be formed on the another side of the first electrode 110 first, and then the steps S10 to S30 are performed to form the electron transport layer 150, the quantum dot light-emitting layer 130, the hole transport doped layer 160, the second electrode 120 and other film layers on a side of the first electrode 110 away from the reflective layer 191, which are not listed one by one here.

Referring to FIG. 8. In some examples, a light extraction layer 192 is further formed on a side of the second electrode 120 away from the quantum dot light-emitting layer 130. In this case, the light extraction layer 192 may be formed after the step S30, that is, after the second electrode 120 is formed. The light extraction layer 192 may be formed by evaporation.

When the light extraction layer 192 is formed by evaporation, the second electrode 120 will not be subjected to an impact, so as to reduce probability of the second electrode 120 being damaged due to the impact. Moreover, the light extraction layer 192 formed by evaporation has good film formation uniformity and is suitable for large-scale film formation.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A light-emitting device, comprising:
a first electrode and a second electrode;
a quantum dot light-emitting layer located between the first electrode and the second electrode; and
a hole transport doped layer located between the quantum dot light-emitting layer and the second electrode; the hole transport doped layer including a mixture of a first hole transport material and a metal material.

2. The light-emitting device according to claim 1, wherein
a mobility of the metal material is greater than a mobility of the first hole transport material.

3. The light-emitting device according to claim 1, wherein
a ratio of an equivalent thickness of the metal material to an equivalent thickness of the first hole transport material is in a range of 1:50 to 1:1, inclusive.

4. The light-emitting device according to claim 1, wherein
a highest occupied molecular orbital energy level of the first hole transport material is in a range of −5 eV to −7 eV, inclusive.

5. The light-emitting device according to claim 1, wherein
the first hole transport material is an organic material.

6. The light-emitting device according to claim 1, wherein
a thickness of the hole transport doped layer is in a range of 10 nm to 60 nm, inclusive.

7. The light-emitting device according to claim 1, further comprising:
a hole injection layer located between the hole transport doped layer and the second electrode, wherein a work function of the metal material is shallower than a highest occupied molecular orbital energy level of the hole injection layer.

8. The light-emitting device according to claim 1, wherein
a work function of the metal material is in a range of −2.2 eV to −4.7 eV, inclusive.

9. The light-emitting device according to claim 1, further comprising:
an electron blocking layer located between the quantum dot light-emitting layer and the hole transport doped layer, wherein the electron blocking layer includes a second hole transport material, and a lowest unoccupied molecular orbital energy level of the second hole transport material is shallower than a lowest unoccupied molecular orbital energy level of the quantum dot light-emitting layer.

10. The light-emitting device according to claim 9, wherein
a thickness of the electron blocking layer is in a range of 5 nm to 50 nm, inclusive.

11. The light-emitting device according to claim 9, wherein
a lowest unoccupied molecular orbital energy level of the electron blocking layer is in a range of −2 eV to −3 eV, inclusive.

12. The light-emitting device according to claim 1, further comprising:
an electron transport layer located between the first electrode and the quantum dot light-emitting layer.

13. A display panel, comprising:
a substrate; and
a plurality of light-emitting devices each according to claim 1, the plurality of light-emitting devices being disposed on the substrate.

14. A display apparatus, comprising the display panel according to claim 13.

15. A method for manufacturing a light-emitting device, comprising:
forming a quantum dot light-emitting layer on a side of a first electrode;
forming a hole transport doped layer on a side of the quantum dot light-emitting layer away from the first electrode, wherein the hole transport doped layer includes a mixture of a first hole transport material and a metal material; and
forming a second electrode on a side of the hole transport doped layer away from the quantum dot light-emitting layer.

16. The method for manufacturing the light-emitting device according to claim 15, wherein
forming the hole transport doped layer on the side of the quantum dot light-emitting layer away from the first electrode, includes:
depositing the first hole transport material and the metal material simultaneously on the side of the quantum dot light-emitting layer away from the first electrode using a dual-source co-evaporation method to form the hole transport doped layer.

17. The method for manufacturing the light-emitting device according to claim 15, wherein
after forming the hole transport doped layer on the side of the quantum dot light-emitting layer away from the first electrode, the method further comprises:
forming a hole injection layer on the side of the hole transport doped layer away from the quantum dot light-emitting layer, wherein a work function of the metal material is shallower than a highest occupied molecular orbital energy level of the hole injection layer; and
forming the second electrode on the side of the hole transport doped layer away from the quantum dot light-emitting layer, includes:
forming the second electrode on a side of the hole injection layer away from the quantum dot light-emitting layer.

18. The method for manufacturing the light-emitting device according to claim 15, wherein
after forming the quantum dot light-emitting layer on the side of the first electrode, the method further comprises:
forming an electron blocking layer on the side of the quantum dot light-emitting layer away from the first electrode, wherein the electron blocking layer includes a second hole transport material, and a lowest unoccupied molecular orbital energy level of the second hole transport material is shallower than a lowest unoccupied molecular orbital energy level of the quantum dot light-emitting layer; and
forming the hole transport doped layer on the side of the quantum dot light-emitting layer away from the first electrode, includes:
forming the hole transport doped layer on a side of the electron blocking layer away from the quantum dot light-emitting layer.

19. The method for manufacturing the light-emitting device according to claim 15, wherein
before forming the quantum dot light-emitting layer on the side of the first electrode, the method further comprises:
forming an electron transport layer on the side of the first electrode; and
forming the quantum dot light-emitting layer on the side of the first electrode, includes:
forming the quantum dot light-emitting layer on a side of the electron transport layer away from the first electrode.
